(19) United States
(12) Patent Application Publication
(10) Pub. No.: US 2026/0173673 A1
(43) Pub. Date: Jun. 18, 2026

(54) DISPLAY DEVICE, METHOD OF MANUFACTURING DISPLAY DEVICE, AND ELECTRONIC DEVICE INCLUDING THE DISPLAY DEVICE

(71) Applicant: Samsung Display Co., Ltd., Yongin-si (KR)

(72) Inventors: PIL SOON HONG, Yongin-si (KR); SEON-IL KIM, Yongin-si (KR); JEONG WON KIM, Yongin-si (KR); JUNHONG PARK, Yongin-si (KR); KABJONG SEO, Yongin-si (KR); SEONHWA CHOI, Yongin-si (KR)

(21) Appl. No.: 19/419,401

(22) Filed: Dec. 15, 2025

(30) Foreign Application Priority Data
Dec. 17, 2024 (KR) 10-2024-0189086

(51) Int. Cl. H10K 59/124; H10K 59/12; H10K 59/122; H10K 59/123

(52) U.S. Cl. CPC H10K 59/124; H10K 59/1201; H10K 59/122; H10K 59/123

(57) ABSTRACT

An embodiment of the disclosure discloses a display device including: a substrate; a thin-film transistor on the substrate; a first insulating layer located on the thin-film transistor and including a concave portion defined in the first insulating layer; a light emitting element disposed in the concave portion and electrically connected to the thin-film transistor; and an auxiliary electrode disposed on a bottom surface and an inner surface of the concave portion and electrically connected to the thin-film transistor and the light emitting element, wherein the light emitting element includes: a pixel electrode in contact with a portion of the auxiliary electrode disposed on the inner surface of the concave portion; an intermediate layer located on the pixel electrode; and a common electrode located on the intermediate layer.

This application claims priority to Korean Patent Application No. 10-2024-0189086, filed on Dec. 17, 2024, and all the benefits accruing therefrom under 35 U.S.C. § 119, the content of which in its entirety is herein incorporated by reference.

### BACKGROUND

### 1. Field

The disclosure relates to a display device, a method of manufacturing a display device, and an electronic device including the display device.

### 2. Description of the Related Art

Recently, various types of lightweight and compact flat panel display devices have been developed. Flat panel display devices include liquid crystal displays (LCDs), field emission displays (FEDs), plasma display panels (PDPs), organic light emitting displays, and the like.

Among flat panel display devices, organic light emitting displays may display images using organic light-emitting diodes (OLEDs) which emit light by the recombination of electrons and holes. Such organic light emitting displays are attracting attention as next-generation displays because the organic light emitting displays have a high response speed and operate with low power consumption.

The above background technology is technical information that the inventor(s) possessed for conceiving of the disclosure or acquired in the process of conceiving of the disclosure, and should not be considered to be prior art already known to the public prior to the filing of the disclosure.

### SUMMARY

The disclosure provides a display device having improved integration and an electronic device including the display device.

The technical problems to be solved by the disclosure are not limited to those described herein, and other problems of the disclosure not mentioned will be more apparent from the following description and will be more clearly understood from embodiments of the disclosure. It will also be appreciated that the above and other objectives and advantages of the disclosure may be realized by means disclosed in the claims and combinations thereof.

Embodiments of the disclosure disclose a display device including: a substrate; a thin-film transistor on the substrate; a first insulating layer located on the thin-film transistor and including a concave portion defined in the first insulating layer; a light emitting element disposed in the concave portion and electrically connected to the thin-film transistor; and an auxiliary electrode disposed on a bottom surface and an inner surface of the concave portion and electrically connected to the thin-film transistor and the light emitting element, wherein the light emitting element includes: a pixel electrode in contact with a portion of the auxiliary electrode disposed on the inner surface of the concave portion; an intermediate layer located on the pixel electrode; and a common electrode located on the intermediate layer.

In an embodiment, the display device may further include a connecting electrode extending through the first insulating layer and electrically connecting the auxiliary electrode and the thin-film transistor.

In an embodiment, the display device may further include a second insulating layer located between the auxiliary electrode and the pixel electrode.

In an embodiment, the second insulating layer may include at least one of an imide-based polymer, a styrene-based polymer, a phenol-based polymer, an acrylic polymer, an aryl ether-based polymer, a fluorinated polymer, a p-xylene-based polymer, or a vinyl alcohol-based polymer.

In an embodiment, the display device may further include a pixel-defining layer located on the first insulating layer and defining a light emitting area of the light emitting element, wherein the common electrode extends above the pixel-defining layer.

In an embodiment, a portion of the pixel-defining layer may extend into the concave portion and may be in contact with the second insulating layer.

In an embodiment, the pixel electrode and the auxiliary electrode may be spaced apart from each other by the portion of the pixel-defining layer.

In an embodiment, the auxiliary electrode may include at least one opening extending through the auxiliary electrode in a thickness direction, and the second insulating layer may be in contact with the first insulating layer through the at least one opening.

In an embodiment, the at least one opening may be located in at least one of a bottom or a wall of the auxiliary electrode.

In an embodiment, the bottom surface of the concave portion may include a flat surface.

Other embodiments of the disclosure disclose a method of fabricating a display device, the method including: forming a concave portion by patterning a first insulating layer which covers a connecting electrode electrically connected to a thin-film transistor on a substrate; depositing an auxiliary electrode on a bottom surface and an inner surface of the concave portion, wherein the auxiliary electrode is electrically connected to the connecting electrode; forming a second insulating layer on the auxiliary electrode; and depositing a pixel electrode on the second insulating layer after patterning the second insulating layer, wherein the pixel electrode is in contact with a portion of the auxiliary electrode disposed on the inner surface of the concave portion.

In an embodiment, the method may further include planarizing an upper surface of the bottom surface of the concave portion.

In an embodiment, the method may further include, after the depositing of the pixel electrode, exposing at least a portion of the second insulating layer by patterning the pixel electrode.

In an embodiment, the method may further include forming a pixel-defining layer which covers a periphery of the pixel electrode.

In an embodiment, the method may further include depositing an intermediate layer including an organic material, and depositing a common electrode on the intermediate layer to extend above the pixel-defining layer.

In an embodiment, the method may further include, after the depositing of the auxiliary electrode, forming at least one opening exposing at least a portion of the first insulating layer by patterning the auxiliary electrode.

In an embodiment, the at least one opening may be located in at least one of a bottom or a wall of the auxiliary electrode, and the second insulating layer may be in contact with the first insulating layer through the at least one opening.

Other embodiments of the disclosure disclose an electronic device including: a memory which stores at least one program; a processor which operates by executing the at least one program; a display device which provides visual information based on data received by the display device from the processor; and a power module which supplies power to the display device, wherein the display device includes: a substrate; a thin-film transistor on the substrate; a first insulating layer located on the thin-film transistor and including a concave portion defined in the first insulating layer; a light emitting element disposed in the concave portion and electrically connected to the thin-film transistor; and an auxiliary electrode disposed on a bottom surface and an inner surface of the concave portion and electrically connected to the thin-film transistor and the light emitting element, wherein the light emitting element includes: a pixel electrode in contact with a portion of the auxiliary electrode disposed on the inner surface of the concave portion; an intermediate layer located on the pixel electrode; and a common electrode located on the intermediate layer.

In an embodiment, the electronic device may further include a connecting electrode extending through the first insulating layer and electrically connecting the auxiliary electrode and the thin-film transistor.

In an embodiment, the electronic device may further include a second insulating layer located between the auxiliary electrode and the pixel electrode.

### BRIEF DESCRIPTION OF THE DRAWINGS

The following drawings attached to this specification illustrate example embodiments of the disclosure and, together with the detailed description of the disclosure described herein, serve to provide further understanding of the technical idea of the disclosure, and therefore, the disclosure should not be interpreted as being limited to the matters illustrated in the drawings in which:

FIG. 1 is a plan view schematically illustrating an example of a display device according to an embodiment of the disclosure;

FIG. 2 is a perspective view schematically illustrating the bent shape of the display device of FIG. 1;

FIG. 3 is a block diagram schematically illustrating the structure of the display device of FIG. 1;

FIG. 4 is a circuit diagram illustrating an example of an equivalent circuit of a subpixel of the display device of FIG. 1;

FIG. 5 is a cross-sectional view schematically illustrating an example of the A-A′ cross-section of FIG. 1;

FIGS. 6 to 10 are cross-sectional views schematically illustrating an example of a manufacturing method for placing the light emitting element of FIG. 5 on a connecting electrode;

FIG. 11 is a cross-sectional view schematically illustrating another example of the A-A′ cross-section of FIG. 1;

FIG. 12 is a cross-sectional view schematically illustrating an example of the E-E′ cross-section of FIG. 11;

FIG. 13 is a cross-sectional view schematically illustrating another example of the E-E′ cross-section of FIG. 11;

FIG. 14 is a cross-sectional view schematically illustrating another example of the E-E′ cross-section of FIG. 11;

FIG. 15 is a cross-sectional view schematically illustrating another example of the A-A′ cross-section of FIG. 1;

FIG. 16 is a block diagram of an electronic device according to an embodiment; and

FIG. 17 illustrates schematic views of electronic devices according to various embodiments.

### DETAILED DESCRIPTION

The disclosure may have various modifications and various embodiments, and thus specific embodiments are illustrated in the drawings and described in detail in the detailed description. The effects and features of the disclosure and how to accomplish the same will be apparent with reference to the following detailed description together with the drawings. However, the disclosure is not limited to embodiments disclosed below, but may be implemented in various forms.

In the following embodiments, terms, such as first and second, as used herein do not have a limiting meaning but are used for the purpose of distinguishing one element from another.

In the following embodiments, singular forms include plural referents unless the context clearly indicates otherwise.

In the following embodiments, terms, such as “comprising” or “having”, are intended to imply the presence of a feature or element described in the specification and do not preclude the possibility that one or more other features or elements may be added.

In the following embodiments, when a portion, such as a unit, area, or element, is referred to as being above or on another portion, the portion may be directly above or on the other portion or an intervening portion, such as a unit, area, or element, may also be present between the two portions.

In the drawings, elements may be exaggerated or reduced in size for ease of explanation. For example, the sizes and thicknesses of the respective elements illustrated in the drawings are arbitrary for ease of explanation, and therefore the following embodiments are not necessarily limited thereto.

It should be appreciated that various embodiments of the disclosure and the terms used therein are not intended to limit the technological features set forth herein to particular embodiments and include various changes, equivalents, or replacements for a corresponding embodiment. With regard to the description of the drawings, similar reference numerals may be used to refer to similar or related elements. It is to be understood that a singular form of a noun corresponding to an item may include one or more of the things, unless the relevant context clearly indicates otherwise. As used herein, each of such phrases as “A or B”, “at least one of A and B”, “at least one of A or B”, “A, B, or C”, “at least one of A, B, and C”, and “at least one of A, B, or C”, may include any one of, or all possible combinations of the items enumerated together in a corresponding one of the phrases.

Hereinafter, embodiments of the disclosure will be described in detail with reference to the accompanying drawings, in which identical or corresponding elements are designated by the same reference numerals.

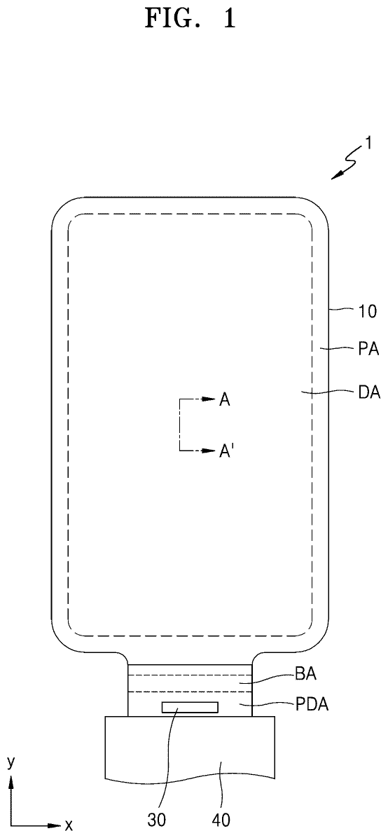

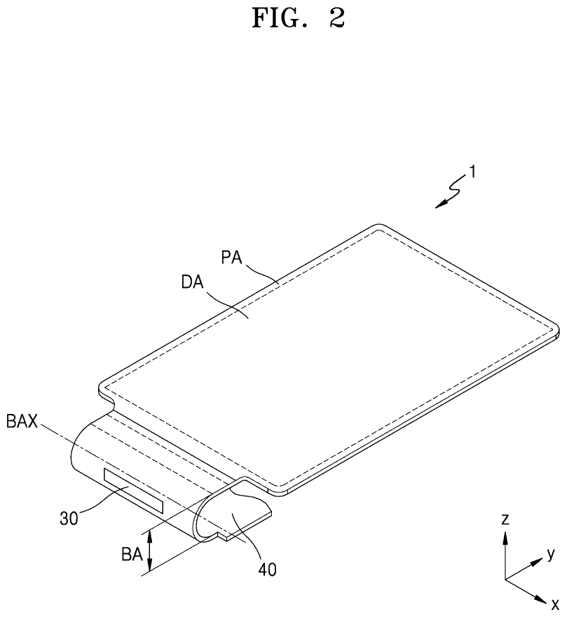

FIG. 1 is a plan view schematically illustrating an example of a display device according to an embodiment of the disclosure, and FIG. 2 is a perspective view schematically illustrating the bent shape of the display device of FIG. 1.

Referring to FIGS. 1 and 2, a display device 1 is a device which displays a moving image or a still image, and may display an image on the screen of a display panel 10 or perform data input and output operations. The display device 1 of this type may be used as a display screen of various electronic devices such as, for example, a mobile phone, a smartphone, a tablet personal computer, a mobile communication terminal, an electronic notebook, an electronic book, a portable multimedia player (PMP), a navigation device, an ultra-mobile PC (UMPC), and the like, as well as a television (TV), a laptop, a monitor, a billboard, an Internet of things (IOT) device, and the like. In some aspects, the display device 1 according to an embodiment may be used in electronic devices, such as, for example, wearable devices, for example, a smart watch, a watch phone, a glasses-type display, and a head mounted display (HMD). In some aspects, the display device 1 according to an embodiment may be used as a display of various electronic devices, such as, for example, a dashboard of an automobile, a center information display (CID) disposed on a center fascia or dashboard of an automobile, a room mirror display replacing a side mirror of an automobile, and a display disposed on the back of a front seat as entertainment for a rear seat of an automobile.

The display device 1 according to an embodiment of the disclosure may include a display area DA in which a plurality of pixels are located and a peripheral area PA located outside the display area DA. Furthermore, the peripheral area PA may include a pad area PDA located on a side of the display area DA, the pad area PDA being a region to which various electronic elements such as, for example, an integrated circuit 30 and a flexible circuit board 40 are electrically attached, and a bending area BA between the display area DA and the pad area PDA. The display area DA, the peripheral area PA, the pad area PDA, and the bending area BA may be defined on a substrate.

FIG. 1 is a plan view illustrating the shape of a substrate and the like during a fabrication process of the display device 1, and the bending area BA of the substrate or the like may be bent about the bending axis BAX extending in a first direction x, as illustrated in FIG. 2. In this case, the bending direction is set such that that the pad area PDA is located behind the display area DA. Accordingly, the area of the peripheral area PA perceived by the user may be minimized.

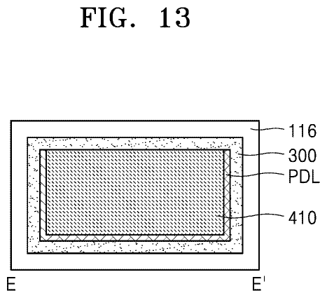

A circuit cover (C-IC in FIG. 13) may be attached to the integrated circuit 30 and the flexible circuit board 40 of the pad area PDA. The circuit cover (C-IC) may protect the integrated circuit 30 and the flexible circuit board 40 from mechanical impact and add waterproof and insulation performance to the integrated circuit 30 and the flexible circuit board 40.

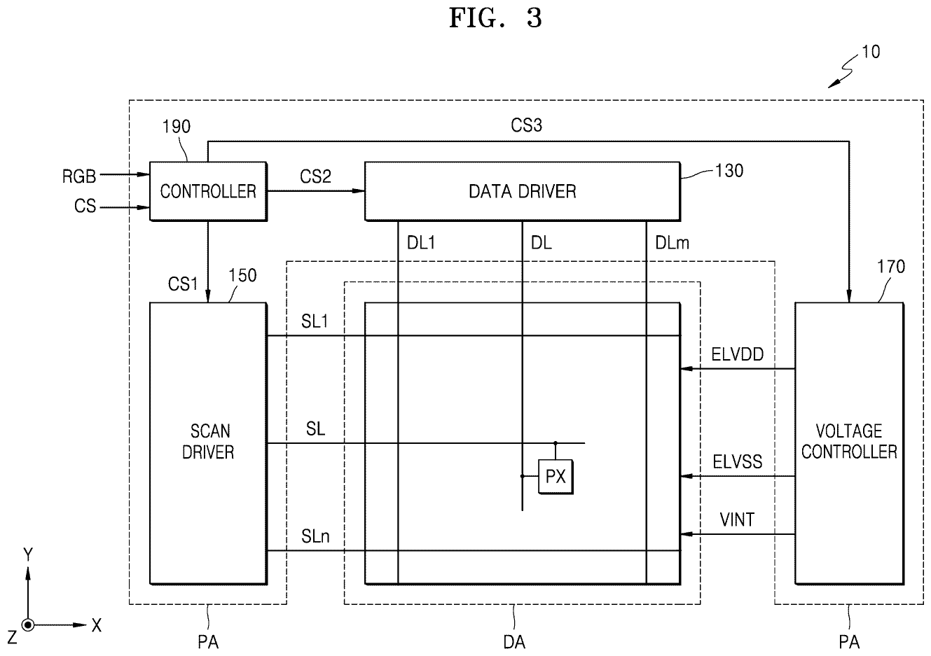

FIG. 3 is a block diagram schematically illustrating the structure of the display device of FIG. 1.

Referring to FIG. 3, a plurality of scan lines SL1, . . . , and SLn extending in a first direction x, a plurality of data lines DL1, . . . , and DLm extending in a second direction y perpendicular to the first direction x, and a plurality of subpixels PX may be located in the display area DA. In this case, each of m and n is a natural number.

The wiring capable of applying electrical signals to the plurality of subpixels PX may include the plurality of scan lines SL1, . . . , and SLn, the plurality of data lines DL1, . . . , and DLm, and the like. The plurality of scan lines SL1, . . . , and SLn may be arranged, for example, in a plurality of rows extending in the first direction x to transmit scan signals to the subpixels PX, the plurality of data lines DL1, . . . , and DLm may be arranged, for example, in a plurality of columns extending in a second direction y to transmit data signals to the subpixels PX, and the plurality of subpixels PX may be located at intersections of the plurality of scan lines SL1, . . . , and SLn and the plurality of data lines DL1, . . . , and DLm.

Each of the subpixels PX may include a light emitting element which may emit red, green, blue, or white light. For example, each the subpixels PX may include, but is not limited to, an organic light-emitting diode (OLED) as a light emitting element.

A data driver 130 which provides data signals to the display area DA, a scan driver 150 which provides scan signals to the display area DA, a voltage controller 170 which controls voltages supplied to the display area DA, and a controller 190 capable of controlling the data driver 130, the scan driver 150, and the voltage controller 170 may be disposed in the peripheral area PA.

The voltage controller 170 may generate and control a first voltage ELVDD, a second voltage ELVSS, and an initialization voltage VAINT provided to the display area DA.

The first voltage ELVDD, the second voltage ELVSS, and the initialization voltage VAINT may be applied to the plurality of subpixels PX. For example, the first voltage ELVDD may be a positive voltage, and the second voltage ELVSS may be a negative voltage or a ground voltage. For example, the second voltage ELVSS may have a lower level than the first voltage ELVDD.

The controller 190 may receive image signals RGB and control signals CS from an external source (e.g., a system board). The controller 190 may convert the data format of the image signals RGB to match the interface specification of the data driver 130 and generate image data DATA. The controller 190 may provide image data DATA having the converted data format to the data driver 130.

The controller 190 may generate and output a first control signal CS1 and a second control signal CS2 in response to a control signal CS provided from an external source. The first control signal CS1 may be defined as a scan control signal, and the second control signal CS2 may be defined as a data control signal. The first control signal CS1 may be provided to the scan driver 150. The second control signal CS2 may be provided to the data driver 130.

The scan driver 150 may generate a plurality of scan signals in response to the first control signal CS1. The plurality of scan signals may be applied to the plurality of subpixels PX via a plurality of scan lines SL1, . . . , and SLn.

The data driver 130 may generate a plurality of data voltages corresponding to image data DATA in response to the second control signal CS2. The plurality of data voltages may be applied to the plurality of subpixels PX via data lines DL1, . . . , and DLm. The data driver 130 may provide the data voltages generated in a subpixel row-specific manner to the plurality of subpixels PX to data lines DL1, . . . , and DLm at the same time.

The plurality of subpixels PX may be provided with the plurality of data voltages in response to the plurality of scan signals. The plurality of subpixels PX may display an image by emitting light at brightness levels corresponding to the plurality of data voltages. The plurality of subpixels PX may display the image by emitting light sequentially or simultaneously.

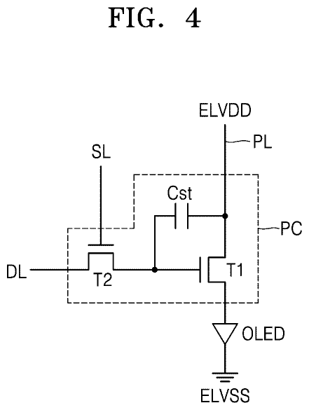

FIG. 4 is a circuit diagram illustrating an example of an equivalent circuit of a subpixel of the display device of FIG. 1.

Referring to FIG. 4, a pixel circuit PC may be connected to a display element, for example, an organic light-emitting diode OLED. The pixel circuit PC may be disposed in the display area DA. The pixel circuit PC may include a driving thin-film transistor T1, a switching thin-film transistor T2, and a storage capacitor Cst. Furthermore, the organic light-emitting diode OLED may emit red, green, or blue light, or may emit red, green, blue, or white light.

The switching thin-film transistor T2 may be connected to a scan line SL and a data line DL, and transmit a data signal or a data voltage input from the data line DL to the driving thin-film transistor T1 based on a scan signal or a switching voltage input from the scan line SL. The storage capacitor Cst may be connected to the switching thin-film transistor T2 and a driving voltage line PL, and may store a voltage corresponding to the difference between the voltage received from the switching thin-film transistor T2 and a first voltage ELVDD which is supplied to the driving voltage line PL.

The driving thin-film transistor T1 may be connected to the driving voltage line PL and the storage capacitor Cst, and may control a driving current flowing through an organic light-emitting diode OLED from the driving voltage line PL in response to the voltage value stored in the storage capacitor Cst. The organic light-emitting diode OLED may emit light having a selected brightness depending on the driving current. The counter electrode of the organic light-emitting diode OLED may be supplied with a second voltage ELVSS.

Although FIG. 3 illustrates the pixel circuit PC including two thin-film transistors and a single storage capacitor, the pixel circuit PC may include three, four, five or more thin-film transistors, and include two, three or more capacitors.

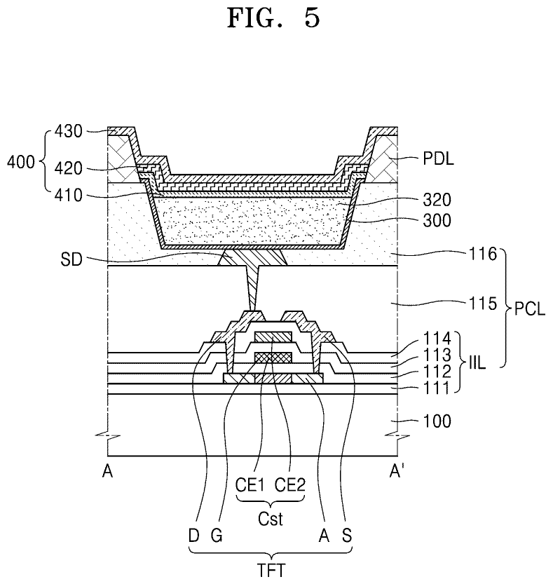

FIG. 5 is a cross-sectional view schematically illustrating an example of the A-A′ cross-section of FIG. 1.

Referring to FIG. 5, the display device 1 may include a display panel 10. Furthermore, the display panel 10 may include a substrate 100, a buffer layer 111, a pixel circuit layer PCL.

The substrate 100 may be formed of a transparent glass material having SiO₂ as the main element. However, this is not intended to be limiting, and the substrate 100 may also be formed of a transparent plastic material. Plastic materials may include polyethersulfone (PES), polyacrylate (PAR), polyetherimide (PEI), polyethylene naphthenate (PEN), polyethylene terephthalate (PET), polyphenylene sulfide (PPS), polyallylate, polyimide, polycarbonate (PC), cellulose triacetate (TAC), cellulose acetate propionate (CAP), and the like. In an embodiment, the substrate 100 may have a multiple-layer structure including a base layer including the described polymer resin and a barrier layer (not illustrated). The substrate 100 including a polymer resin may have flexible, rollable, and bendable properties.

The buffer layer 111 may be disposed on the substrate 100. The buffer layer 111 may include an inorganic insulating material, such as, for example, silicon nitride, silicon oxynitride, and silicon oxide, and may be a single layer or a plurality of layers including the described inorganic insulating material.

The pixel circuit layer PCL may be disposed on the buffer layer 111. The pixel circuit layer PCL may include a thin-film transistor TFT included in the pixel circuit and an inorganic insulating layer IIL, a planarization layer 115, and a first insulating layer 116 disposed under and/or over the elements of the thin-film transistor TFT. The inorganic insulating layer IIL may include a first gate insulating layer 112, a second gate insulating layer 113, and an interlayer insulating layer 114.

The thin-film transistor TFT may include a semiconductor layer A, and the semiconductor layer A may include polysilicon. In another example, the semiconductor layer A may include amorphous silicon, an oxide semiconductor, an organic semiconductor, or the like. The semiconductor layer A may include a channel region and a drain region and a source region disposed on opposite sides of the channel region, respectively. The gate electrode G may overlap the channel region.

The gate electrode G may include a low-resistance metal material. The gate electrode G may include a conductive material including molybdenum (Mo), aluminum (AI), copper (Cu), titanium (Ti), and the like, and may be formed as a single layer or a plurality of layers including the described materials.

The first gate insulating layer 112 between the semiconductor layer A and the gate electrode G may include an inorganic insulating material, such as, for example, silicon oxide (SiO₂), silicon nitride (SiNX), silicon oxynitride (SiON), aluminum oxide (Al₂O₃), titanium oxide (TiO₂), tantalum oxide (Ta₂O₅), hafnium oxide (HfO₂), or zinc oxide (ZnOX). Zinc oxide (ZnOX) may be zinc oxide (ZnO) and/or zinc peroxide (ZnO₂).

The second gate insulating layer 113 may be provided to cover the gate electrode G. The second gate insulating layer 113 may, similarly to the first gate insulating layer 112, include an inorganic insulating material such as, for example, silicon oxide (SiO₂), silicon nitride (SiNX), silicon oxynitride (SiON), aluminum oxide (Al₂O₃), titanium oxide (TiO₂), tantalum oxide (Ta₂O₅), hafnium oxide (HfO₂), or zinc oxide (ZnOx). Zinc oxide (ZnOX) may be zinc oxide (ZnO) and/or zinc peroxide (ZnO₂).

An upper electrode CE2 of a storage capacitor Cst may be disposed on the second gate insulating layer 113. The upper electrode CE2 may overlap the gate electrode G located under the upper electrode CE2. In this case, the gate electrode G and the upper electrode CE2 overlapping on opposite sides of the second gate insulating layer 113 may form the storage capacitor Cst of the pixel circuit. That is, the gate electrode G may function as a lower electrode CE1 of the storage capacitor Cst. In this manner, the storage capacitor Cst and the thin-film transistor TFT may be formed to overlap each other. However, this is not intended to be limiting, and in some embodiments, the storage capacitor Cst may be formed so as not to overlap the thin-film transistor TFT.

The upper electrode CE2 may include aluminum (Al), platinum (Pt), palladium (Pd), silver (Ag), magnesium (Mg), gold (Au), nickel (Ni), neodymium (Nd), iridium (Ir), chromium (Cr), calcium (Ca), molybdenum (Mo), titanium (Ti), tungsten (W), and/or copper (Cu), and may be a single layer or a plurality of layers of the described materials.

The interlayer insulating layer 114 may cover the upper electrode CE2. The interlayer insulating layer 114 may include silicon oxide (SiO₂), silicon nitride (SiNX), silicon oxynitride (SiON), aluminum oxide (Al₂O₃), titanium oxide (TiO₂), tantalum oxide (Ta₂O₅), hafnium oxide (HfO₂), zinc oxide (ZnOx), or the like. Zinc oxide (ZnOX) may be zinc oxide (ZnO) and/or zinc peroxide (ZnO₂). The interlayer insulating layer 114 may be a single layer or a plurality of layers including the described inorganic insulating material.

The drain electrode D and the source electrode S may each be located on the interlayer insulating layer 114. The drain electrode D and the source electrode S may include a material having good conductivity. The drain electrode D and the source electrode S may include a conductive material including molybdenum (Mo), aluminum (Al), copper (Cu), titanium (Ti), and the like, and may be formed as a plurality of layers or a single layer including the described materials. In an embodiment, the drain electrode D and the source electrode S may have a multiple-layer structure of Ti/Al/Ti.

The planarization layer 115 may be disposed such that the planarization layer 115 covers the drain electrode D and the source electrode S. The planarization layer 115 may include an organic insulating layer. The planarization layer 115 may include an organic insulator, such as, for example, a general-purpose polymer (e.g., polymethylmethacrylate (PMMA) or polystyrene (PS)), a polymer derivative having a phenol group, an acrylic polymer, an imide polymer, an aryl ether polymer, an amide polymer, a fluorinated polymer, a p-xylene polymer, a vinyl alcohol polymer, and blends thereof.

A connecting electrode SD may be disposed on the planarization layer 115. In this case, the connecting electrode SD may be connected to the drain electrode D or the source electrode S through a contact hole of the planarization layer 115. The connecting electrode SD may include a material having high conductivity. The connecting electrode SD may include a conductive material including molybdenum (Mo), aluminum (Al), copper (Cu), titanium (Ti), and the like, and may be formed as a plurality of layers or a single layer including the described materials. In an embodiment, the connecting electrode SD may have a multiple-layer structure of Ti/Al/Ti.

The first insulating layer 116 may be disposed such that the first insulating layer 116 covers the connecting electrode SD. The first insulating layer 116 may include an organic insulating layer. The first insulating layer 116 may include an organic insulator, such as, for example, a general-purpose polymer, (e.g., polymethylmethacrylate (PMMA) or polystyrene (PS)), a polymer derivative having a phenol group, an acrylic polymer, an imide polymer, an aryl ether polymer, an amide polymer, a fluorinated polymer, a p-xylene polymer, a vinyl alcohol polymer, and blends thereof.

The first insulating layer 116 may include a concave portion. As illustrated in FIG. 5, the concave portion may be defined as a region formed by patterning the first insulating layer 116 in the thickness direction of the first insulating layer 116. The concave area may be referred to as a trench.

An auxiliary electrode 300 electrically connected to the connecting electrode SD and a light emitting element 400 may be disposed on the bottom surface and the inner surface of the concave portion. For example, the auxiliary electrode 300 may be electrically connected to the connecting electrode SD provided on the bottom surface of the concave portion, in a shape extending through the first insulating layer 116. Furthermore, in an example, the auxiliary electrode 300 may be provided such that the auxiliary electrode 300 is in contact with a pixel electrode 410 of the light emitting element 400 on the inner surface of the concave portion. For example, a portion of the auxiliary electrode 300 disposed on the inner surface of the concave portion may be in contact with the pixel electrode 410 of the light emitting element 400.

In another example, as illustrated in FIG. 5, the auxiliary electrode 300 may also be disposed on the inner surface of the concave portion of the first insulating layer 116 and on a region of the first insulating layer 116 extending in the direction of a pixel-defining layer PDL described later. In such a case, the pixel electrode 410 may come into contact with the auxiliary electrode 300 in an area extending in the direction of the pixel-defining layer PDL on the inner surface of the concave portion and the first insulating layer 116.

For example, the auxiliary electrode 300 may be a (semi-)transparent electrode or a reflective electrode. In an example in which the auxiliary electrode 300 is a (semi-)transparent electrode, the auxiliary electrode 300 may have a layer formed of a metal having a small work function, i.e., Li, Ca, LiF/Ca, LiF/Al, Al, Ag, Mg, and compounds thereof, and a (semi-)transparent conductive layer such as, for example, ITO, IZO, ZnO, or In₂O₃. In an example in which the auxiliary electrode 300 is a reflective electrode, the auxiliary electrode 300 may have a layer formed of Li, Ca, LiF/Ca, LiF/Al, Al, Ag, Mg, and compounds thereof. The composition and material of the auxiliary electrode 300 are not limited thereto, and the auxiliary electrode may be an electrode including the same material as the connecting electrode SD.

When the auxiliary electrode 300 is a reflective electrode, to improve the reflection characteristics of the auxiliary electrode 300, the bottom surface of the concave portion of the first insulating layer 116 on which the auxiliary electrode 300 is disposed may include a flat surface. That is, the bottom surface of the concave portion of the first insulating layer 116 may be upward facing and have a relatively high flatness.

Conventionally, the connecting electrode SD and the pixel electrode 410 have been electrically connected through a separate contact hole outside the light emitting area of the light emitting element 400. Accordingly, a separate contact hole occupies a space, thereby limiting the integration of the display device. Furthermore, the pixel electrode 410 is provided on a separate contact hole, the width of which is narrower than the width of a second insulating layer 320, instead of on the second insulating layer 320, the upper surface of which has excellent flatness as described later, and thus, the flatness of the lower surface of the pixel electrode 410 is relatively low, thereby resulting in uneven light emission efficiency according to the viewing angle and degraded optical characteristics, such as, for example, a poor reflection color deviation due to uneven reflection of the pixel electrode 410. Here, “flatness” may mean the difference between the maximum and minimum heights of a surface. Furthermore, “low flatness” means that the difference between the maximum and minimum heights of the surface is large. “High flatness” means that the difference between the maximum and minimum heights of the surface is small.

In another example, in the display device according to an embodiment of the disclosure, the connecting electrode SD and the pixel electrode 410 may be electrically connected through the auxiliary electrode 300 in an area overlapping the light emitting area of the light emitting element 400 without a separate contact hole, thereby improving the integration level of the display device.

In another example, the second insulating layer 320 may be provided between the auxiliary electrode 300 and the pixel electrode 410. The second insulating layer 320 may also be referred to as a gap-fill layer. In this case, the second insulating layer 320 may be located under the pixel electrode 410 in the area overlapping the light emitting area, thereby having high flatness. Accordingly, the flatness of the pixel electrode 410 in contact with the upper surface of the second insulating layer 320 may be increased. For example, the flatness of the pixel electrode 410 may be 200 nm or less. As an optional embodiment, the flatness of the pixel electrode 410 may be 50 nm or less.

The second insulating layer 320 may include at least one of an imide-based polymer, a styrene-based polymer, a phenol-based polymer, an acrylic polymer, an aryl ether-based polymer, a fluorinated polymer, a p-xylene-based polymer, or a vinyl alcohol-based polymer.

The pixel electrode 410 may include a conductive oxide such as, for example, indium tin oxide (ITO), indium zinc oxide (IZO), zinc oxide (ZnO), indium oxide (In₂O₃), indium gallium oxide (IGO), or aluminum zinc oxide (AZO). In another embodiment, the pixel electrode 410 may include a reflective film including silver (Ag), magnesium (Mg), aluminum (Al), platinum (Pt), palladium (Pd), gold (Au), nickel (Ni), neodymium (Nd), iridium (Ir), chromium (Cr), or a compound thereof. In another embodiment, the pixel electrode 410 may further include a film formed of ITO, IZO, ZnO or In₂O₃ over/under the described reflective film.

A pixel-defining layer PDL defining the light emitting area of the light emitting element 400 may be disposed on the first insulating layer 116. For example, the pixel-defining layer PDL may be provided on the first insulating layer 116 and cover the periphery of the pixel electrode 410. The pixel-defining layer PDL may serve to define the pixel by having an opening corresponding to each pixel, i.e., an opening through which at least a portion of the light emitting element 400 is exposed. In this case, the opening may be the light emitting area.

Furthermore, the pixel-defining layer PDL may increase the distance between the periphery of the pixel electrode 410 and a common electrode 430, thereby preventing arcs or the like from occurring between the periphery of the pixel electrode 410 and the common electrode 430. The pixel-defining layer PDL may include an organic insulating material and/or an inorganic insulating material. For example, the pixel-defining layer PDL may include polyimide or hexamethyldisiloxane (HMDSO).

In an embodiment, the pixel-defining layer PDL may include a light blocking material, and may be provided to be black. The light blocking material may include a resin or paste including carbon black, carbon nanotubes, or a black dye; metal particles of, for example, nickel, aluminum, molybdenum, and an alloy thereof; metal oxide particles (e.g., chromium oxide particles); metal nitride particles (e.g., chromium nitride particles); or the like. In an example in which the pixel-defining layer PDL includes a light blocking material, the reflection of external light by a metal structure disposed under the pixel-defining layer PDL may be reduced.

A spacer may be disposed on the pixel-defining layer PDL. The spacer may be used to prevent damage to the substrate 100 in a fabrication method of fabricating a display device. A mask sheet may be used in fabrication of the display panel 10, in which case, the mask sheet may enter the opening of the pixel-defining layer PDL or come into close contact with the pixel-defining layer PDL, thereby preventing portion of the substrate 100 from being damaged or destroyed by the mask sheet during deposition of the deposition material on the substrate 100.

The spacer may include an organic insulating material such as, for example, polyimide. In another example, the spacer may include an inorganic insulator such as, for example, silicon nitride or silicon oxide, or may include an organic insulator and an inorganic insulator.

In an embodiment, the spacer may include a material different from the pixel-defining layer PDL. In another embodiment, the spacer may include the same material as the pixel-defining layer PDL, in which case the pixel-defining layer PDL and the spacer may be formed together in a mask process using a halftone mask or the like.

An intermediate layer 420 may be formed on the pixel electrode 410 exposed through the opening of the pixel-defining layer PDL. The intermediate layer 420 may include a low molecular weight material or a high molecular weight material. In an example in which a low molecular weight material is included, a structure in which a hole injection layer (HIL), a hole transport layer (HTL), an emitting layer (EML), an electron transport layer (ETL), and an electron injection layer (EIL) are stacked on each other in a single or composite structure may be provided, and various organic substances including copper phthalocyanine (CuPc), N,N-di(naphthalene-1-yl)-N,N′-diphenyl-benzidine (NPB), and tris-8-hydroxyquinoline aluminum (Alq3) may be included. These layers may be formed by vacuum deposition.

When the intermediate layer 420 includes a polymer material, the intermediate layer 420 may usually have a structure including a hole transport layer (HTL) and an emitting layer (EML). In this case, the hole transport layer may include PEDOT, and the light emitting layer may include a polymer material such as, for example, a poly-phenylenevinylene (PPV)-based material and a polyfluorene-based material. The structure of the intermediate layer 420 is not limited to that described herein and may have various structures. For example, the intermediate layer 420 may include a single layer which spans a plurality of pixel electrodes 410, or may include a layer patterned to correspond to each of the plurality of pixel electrodes 410.

The common electrode 430 may extend above the pixel-defining layer PDL and be disposed on the intermediate layer 420. A common voltage ELVSS may be applied to the common electrode 430, and the common electrode 430 may be disposed such that the common electrode 430 covers the display area (DA in FIG. 1). For example, the common electrode 430 may be formed integrally and cover a plurality of light emitting elements 400. The common electrode 430 may be a (semi-)transparent electrode or a reflective electrode. In an example in which the common electrode 430 is a (semi-)transparent electrode, the common electrode 430 may have a layer formed of a metal having a small work function, i.e., Li, Ca, LiF/Ca, LiF/Al, Al, Ag, Mg, and compounds thereof, and a (semi-)transparent conductive layer such as, for example, ITO, IZO, ZnO, or In₂O₃. In an example in which the common electrode 430 is a reflective electrode, the common electrode 430 may have a layer formed of Li, Ca, LiF/Ca, LiF/Al, Al, Ag, Mg, and a compound thereof. The composition and material of the common electrode 430 are not limited to the above, and various modifications are possible.

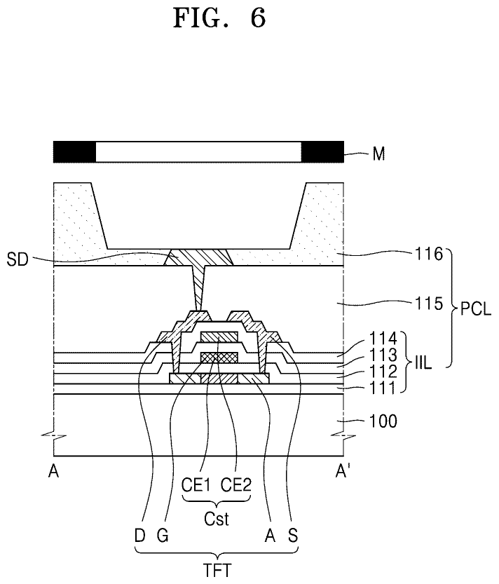

FIGS. 6 to 10 are cross-sectional views schematically illustrating an example of a manufacturing method for placing the light emitting element of FIG. 5 on a connecting electrode.

In the descriptions of the method and processes herein, the operations may be performed in a different order than the order shown and/or described, or the operations may be performed in different orders or at different times. Certain operations may also be omitted, one or more operations may be repeated, or other operations may be added. Descriptions that an element “may be disposed,” “may be formed,” and the like include methods, processes, and techniques for disposing the element, forming the element, and the like in accordance with example aspects described herein.

A method of fabricating a display device according to an embodiment of the disclosure may include operations of: forming a concave portion by patterning a first insulating layer which covers a connecting electrode electrically connected to a thin-film transistor on a substrate; depositing an auxiliary electrode on a bottom surface and an inner surface of the concave portion, wherein the auxiliary electrode is electrically connected to the connecting electrode; forming a second insulating layer on the auxiliary electrode; and depositing a pixel electrode on the second insulating layer after patterning the second insulating layer.

Referring to FIG. 6, the method may include depositing a first insulating layer 116 such that the first insulating layer 116 covers a connecting electrode SD, and then patterning the first insulating layer 116 using a mask M, thereby forming the concave portion exposing the connecting electrode SD. In this case, for example, the method may include performing a process of planarizing the bottom surface (which is upward facing) of the concave portion, on which an auxiliary electrode 300 may be disposed, which may improve the reflection characteristics of the auxiliary electrode 300.

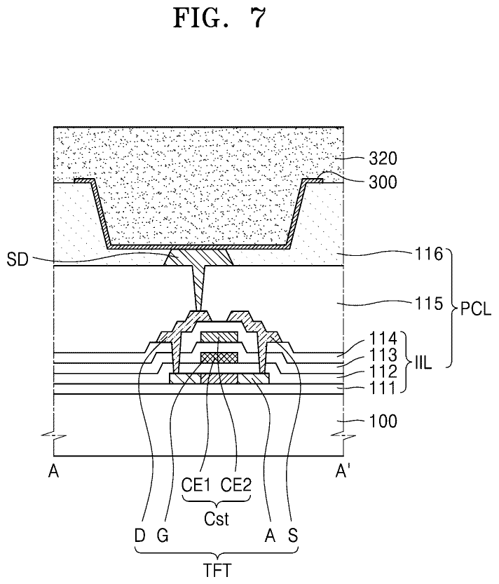

Referring to FIG. 7, the method may include depositing the auxiliary electrode 300 on the bottom surface, the inner surface, and the upper surface of the concave portion of the first insulating layer 116. The auxiliary electrode 300 may be electrically connected to the connecting electrode SD on the bottom surface of the concave portion. Thereafter, the method may include forming a second insulating layer 320 on the auxiliary electrode 300 and the first insulating layer 116.

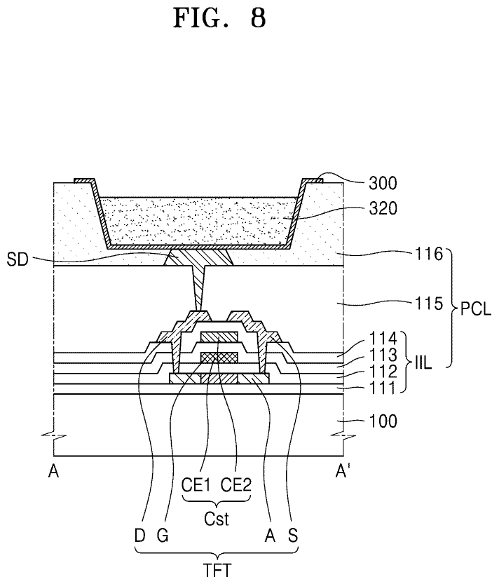

Referring to FIG. 8, the method may include performing a process of patterning the second insulating layer 320 formed on the auxiliary electrode 300 and the first insulating layer 116 such that the second insulating layer 320 (i.e., a remaining portion of the second insulating layer 320) is located in the concave portion. As an optional embodiment, the method may include further performing a process of planarizing the upper surface of the second insulating layer 320, which may improve the flatness of a pixel electrode 410 disposed on the second insulating layer 320.

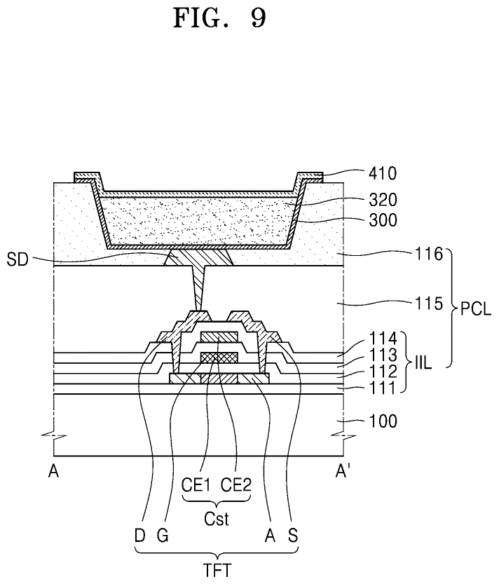

Referring to FIG. 9, the method may include depositing the pixel electrode 410 on a second insulating layer 320 such that the pixel electrode 410 is in contact with the auxiliary electrode 300 formed on the inner surface and the upper surface of the concave portion.

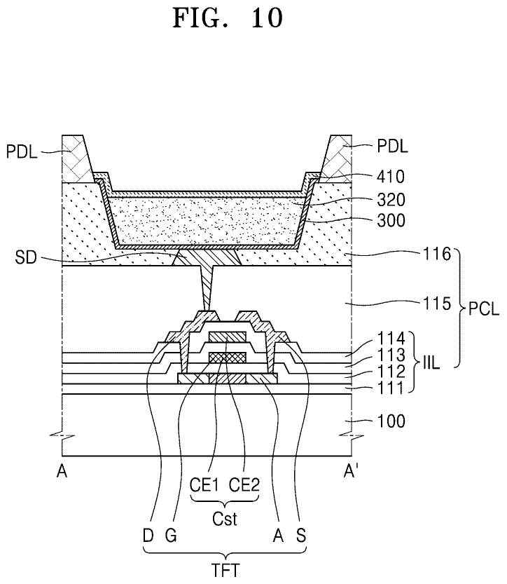

Referring to FIG. 10, the method may include performing a process of forming, on the first insulating layer 116, a pixel-defining layer PDL defining a light emitting area of a light emitting element 400. The pixel-defining layer PDL may be formed on the first insulating layer 116 such that the pixel-defining layer PDL covers the periphery of the pixel electrode 410.

Thereafter, the method may include stacking an intermediate layer 420 including an organic material on the pixel electrode 410 exposed through the opening of the pixel-defining layer PDL, as illustrated in FIG. 5. The method may then include performing an operation of depositing a common electrode 430 extending over the pixel-defining layer PDL on the intermediate layer 420, as illustrated in FIG. 5. Accordingly, for example, the connecting electrode SD and the pixel electrode 410 may be electrically connected through the auxiliary electrode 300 in an area overlapping the light emitting area of the light emitting element 400, without a separate contact hole. In this case, the common electrode 430 may be located such that the common electrode 430 covers the display area (DA in FIG. 1).

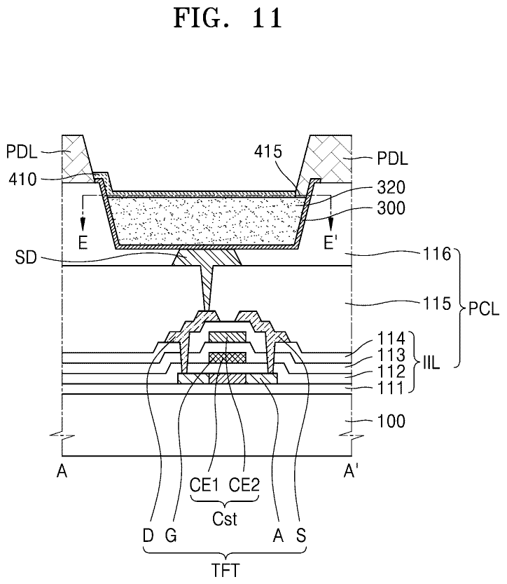

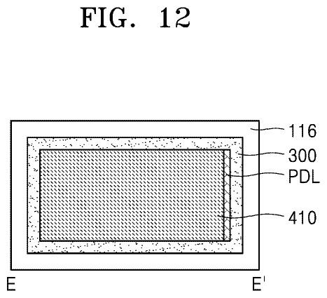

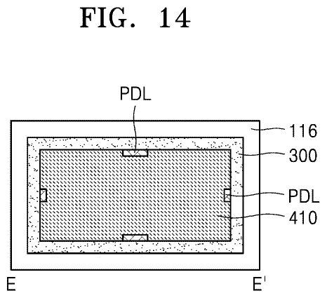

FIG. 11 is a cross-sectional view schematically illustrating another example of the A-A′ cross-section of FIG. 1, FIG. 12 is a cross-sectional view schematically illustrating an example of the E-E′ cross-section of FIG. 11, FIG. 13 is a cross-sectional view schematically illustrating another example of the E-E′ cross-section of FIG. 11, and FIG. 14 is a cross-sectional view schematically illustrating another example of the E-E′ cross-section of FIG. 11.

FIG. 11 is the same as FIG. 5 except for an opening 415 provided in the pixel electrode 410, and therefore, repetitive descriptions will be avoided and only additional portions will be described. In some aspects, FIG. 12 is an example of the cross-section taken along line E-E′ of FIG. 11, and is a cross-section illustrating a plane perpendicular to a direction in which the elements of the display device are stacked.

First, referring to FIGS. 11 and 12, the pixel electrode 410 may include at least one opening 415 extending in the thickness direction of the pixel electrode 410 on the inner side of the concave portion which is in contact with the auxiliary electrode 300. The opening 415 of the described pixel electrode 410 may also be referred to as a vent hole.

As described herein, the second insulating layer 320 may include an organic material. In an example in which the second insulating layer 320 is formed as described herein, a portion of the organic material may be thermally decomposed or chemically reacted while the second insulating layer 320 is being deposited, thereby producing a gaseous by-product, and chemicals, such as, for example, a solvent used in forming the second insulating layer 320, may not be completely volatilized and remain as residues, thereby producing gas. Furthermore, latent gases contained in the organic film may leak due to external environments such as, for example, humidity or temperature.

As In an embodiment of the disclosure, when the pixel electrode 410 includes the opening 415, a passage allowing the gas described herein to be discharged through the opening 415 may be formed, thereby improving the performance and durability of the display device.

The opening 415 of the pixel electrode 410 may be formed by patterning the pixel electrode 410 after the operation of depositing the pixel electrode 410 on the second insulating layer 320. In this case, at least a portion of the second insulating layer 320 may be exposed. Accordingly, a portion of the pixel-defining layer PDL may extend into the concave portion and come into contact with the second insulating layer 320. Furthermore, the pixel electrode 410 and the auxiliary electrode 300 may be spaced apart from each other by the portion (i.e., the extending portion) of the pixel-defining layer PDL.

Referring to FIGS. 11, 13 and 14, FIGS. 13 and 14 illustrate various examples of at least one opening 415 (or vent hole) (see FIG. 11) extending through the pixel electrode 410 in the thickness direction. For example, embodiments of the present disclosure are not limited to implementations in which the opening 415 is disposed in only one direction on the second insulating layer 320, as illustrated in FIG. 11, and if the gas described herein may be discharged through the opening 415, the opening 415 may be arranged in various forms.

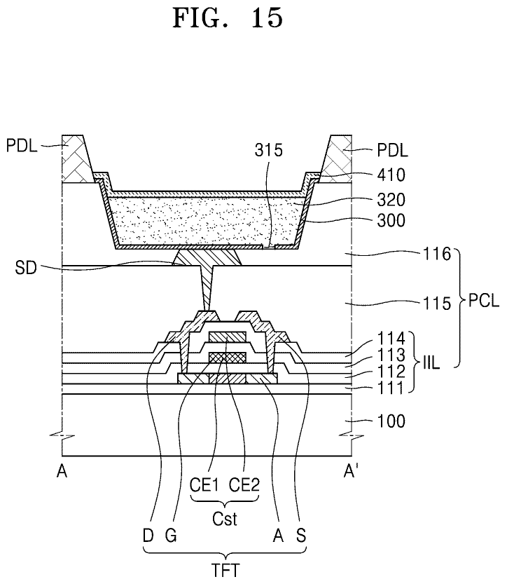

FIG. 15 is a cross-sectional view schematically illustrating another example of the A-A′ cross-section of FIG. 1.

FIG. 15 is the same as FIG. 5 except for an opening 315 provided in the auxiliary electrode 300, and therefore, repetitive descriptions will be avoided and additional portions will be described.

Referring to FIG. 15, the auxiliary electrode 300 may include at least one opening 315 extending through the auxiliary electrode 300 in the thickness direction. The opening 315 of the described auxiliary electrode 300 may also be referred to as a vent hole.

As in an embodiment of the disclosure, when the auxiliary electrode 300 includes the opening 315, a passage allowing the gas described herein in FIG. 11 to be discharged through the opening 315 may be formed, thereby improving the performance and durability of the display device.

The opening 315 of the auxiliary electrode 300 may be formed by patterning the auxiliary electrode 300 after the operation of depositing the auxiliary electrode 300 on the first insulating layer 116. In this case, at least a portion of the first insulating layer 116 may be exposed. Accordingly, the second insulating layer 320 may come into contact with the first insulating layer 116 through the opening 315.

Although a single opening 315 of the auxiliary electrode 300 is illustrated in FIG. 15 as being provided in the bottom of the auxiliary electrode 300, embodiments of the present disclosure are not limited thereto, and a plurality of openings 315 may be provided in the auxiliary electrode 300. In some aspects, a plurality of openings 315 of the auxiliary electrode 300 may be provided in at least one of the bottom or the wall of the auxiliary electrode 300. For example, two openings 315 may be formed in the bottom of the auxiliary electrode 300, or one opening 315 may be formed in the bottom of the auxiliary electrode 300 and one or more openings may be formed in the wall of the auxiliary electrode 300.

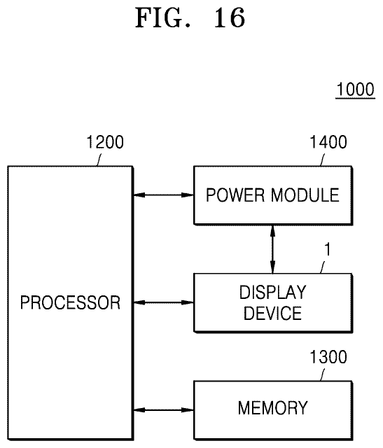

FIG. 16 is a block diagram of an electronic device according to an embodiment.

Referring to FIG. 16, an electronic device 1000 according to an embodiment may include a display device 1, a processor 1200, a memory 1300, and a power module 1400.

The display device 1 may provide visual information by receiving data from the processor 1200. The display device 1 may be the display device 1 according to the described embodiments of the disclosure.

The processor 1200 may include at least one of a central processing unit (CPU), an application processor (AP), a graphic processing unit (GPU), a communication processor (CP), an image signal processor (ISP), or a controller. For example, the processor 1200 may operate by executing at least one program.

The memory 1500 may store data information for operation of the processor 1200 or the display device 1. For example, the memory 1500 may store at least one of the described programs. In an example in which the processor 1200 executes an application stored in the memory 1500, an image data signal and/or an input control signal are transmitted to the display device 1, and the display device 1 may process the received signal and output image information on a display screen.

The power module 1400 may include a power supply module, such as, for example, a power adapter or a battery device, and a power conversion module which converts power supplied by the power supply module to generate power for the operation of the electronic device 1000. For example, the power module 1400 may supply power to the display device 1.

At least one of the elements of the described electronic device 1000 may be included in the display device 1 according to the embodiments described herein. Furthermore, some of the individual modules functionally included in a module may be included in the display device 1 and others may be provided separately from the display device 1.

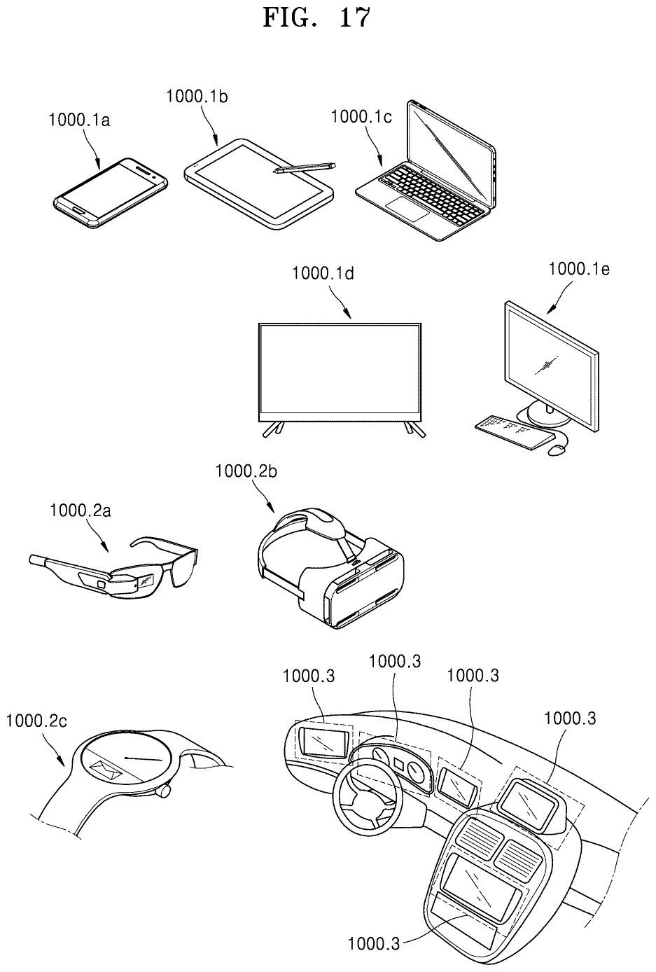

FIG. 17 illustrates schematic views of electronic devices according to various embodiments.

Referring to FIG. 17, each of various electronic devices to which a display device according to embodiments of the disclosure is applied may include not only image display electronic devices, such as, for example, a smart phone 1000.1a, a tablet PC 1000.1b, a laptop 1000.1c, a TV 1000.1d, and a desk monitor 1000.1e, but also wearable electronic devices each including a display device, such as, for example, smart glasses 1000.2a, a head mounted display 1000.2b, and a smart watch 1000.2c, vehicle electronic devices 1000.3 each including a display device, such as, for example, a dashboard, a center fascia, a center information display (CID) disposed on a dashboard, and a room mirror display of an automobile, and the like.

According to embodiments of the disclosure, because the pixel electrode and the connecting electrode are in contact through the auxiliary electrode without a separate contact hole, the integration level of the display device and the electronic device including the same may be improved.

Furthermore, the flatness of the pixel electrode may be improved by disposing the pixel electrode on the flat insulating layer instead of arranging the pixel electrode on a separate contact hole.

However, the effects which may be obtained from the disclosure are not limited to the effects described herein, and other technical effects not described will be clearly understood by a person having ordinary knowledge in the art from the above description of inventions.

The respective embodiments described herein are embodiments which may be practiced independently, the structure of each of the embodiments may be applied in combination with other embodiments.

The disclosure has been described as above with reference to the embodiments illustrated in the drawings, which are non-limiting examples, and a person having ordinary knowledge in the art will appreciate that various modifications and variations of the embodiment are possible. Therefore, the true scope of technical protection of the disclosure should be defined by the technical idea of the appended claims.

The particular implementations described in the embodiments are examples and are not intended to limit the scope of the embodiments in any manner. Furthermore, an element may not be essential to the practice of the disclosure unless the element is specifically described as “essential” or “critical”.

The use of the term “the” and similar reference terms in the context of describing the embodiments (particularly in the claims) are to be construed to cover both the singular and the plural.

Furthermore, the description of ranges in embodiments includes inventions in which individual values within the ranges are applied (unless otherwise stated), as if each individual value within the range were specified in the detailed description.

Finally, the operations of the method according to the disclosure may be performed in any appropriate order, unless the order of the operations is explicitly stated or otherwise. The embodiments are not necessarily limited to the order in which the operations are described.

The use of any examples or any illustrative terms herein is for the purpose of describing the embodiments in detail, and the scope of the embodiments is not limited to the examples or the illustrative terms unless defined by the claims.

Furthermore, a person having ordinary knowledge in the art will appreciate that various modifications, combinations, and alterations are possible depending on the design conditions and factors within the scope of the appended claims or equivalents thereof.

What is claimed is:

1. A display device comprising:
a substrate;
a thin-film transistor on the substrate;
a first insulating layer located on the thin-film transistor and comprising a concave portion defined in the first insulating layer;
a light emitting element disposed in the concave portion and electrically connected to the thin-film transistor; and
an auxiliary electrode disposed on a bottom surface and an inner surface of the concave portion and electrically connected to the thin-film transistor and the light emitting element,
wherein the light emitting element comprises:
a pixel electrode in contact with a portion of the auxiliary electrode disposed on the inner surface of the concave portion;
an intermediate layer located on the pixel electrode; and
a common electrode located on the intermediate layer.

2. The display device of claim 1, further comprising a connecting electrode extending through the first insulating layer and electrically connecting the auxiliary electrode and the thin-film transistor to each other.

3. The display device of claim 1, further comprising a second insulating layer located between the auxiliary electrode and the pixel electrode.

4. The display device of claim 3, wherein the second insulating layer comprises at least one of an imide-based polymer, a styrene-based polymer, a phenol-based polymer, an acrylic polymer, an aryl ether-based polymer, a fluorinated polymer, a p-xylene-based polymer, or a vinyl alcohol-based polymer.

5. The display device of claim 3, further comprising a pixel-defining layer located on the first insulating layer and defining a light emitting area of the light emitting element, wherein the common electrode extends above the pixel-defining layer.

6. The display device of claim 5, wherein a portion of the pixel-defining layer extends into the concave portion and is in contact with the second insulating layer.

7. The display device of claim 6, wherein the pixel electrode and the auxiliary electrode are spaced apart from each other by the portion of the pixel-defining layer.

8. The display device of claim 3, wherein:
the auxiliary electrode comprises at least one opening extending through the auxiliary electrode in a thickness direction, and
the second insulating layer is in contact with the first insulating layer through the at least one opening.

9. The display device of claim 8, wherein the at least one opening is located in at least one of a bottom or a wall of the auxiliary electrode.

10. The display device of claim 1, wherein the bottom surface of the concave portion comprises a flat surface.

11. A method of fabricating a display device, the method comprising:
forming a concave portion by patterning a first insulating layer which covers a connecting electrode electrically connected to a thin-film transistor on a substrate;
depositing an auxiliary electrode on a bottom surface and an inner surface of the concave portion, wherein the auxiliary electrode is electrically connected to the connecting electrode;
forming a second insulating layer on the auxiliary electrode; and
depositing a pixel electrode on the second insulating layer after patterning the second insulating layer,
wherein the pixel electrode is in contact with a portion of the auxiliary electrode disposed on the inner surface of the concave portion.

12. The method of claim 11, further comprising planarizing an upper surface of the bottom surface of the concave portion.

13. The method of claim 11, further comprising, after the depositing of the pixel electrode, exposing at least a portion of the second insulating layer by patterning the pixel electrode.

14. The method of claim 11, further comprising forming a pixel-defining layer which covers a periphery of the pixel electrode.

15. The method of claim 14, further comprising:
depositing an intermediate layer comprising an organic material on the pixel electrode, and
depositing a common electrode on the intermediate layer to extend above the pixel-defining layer.

16. The method of claim 11, further comprising, after the depositing of the auxiliary electrode, forming at least one opening exposing at least a portion of the first insulating layer by patterning the auxiliary electrode.

17. The method of claim 16, wherein:
the at least one opening is located in at least one of a bottom or a wall of the auxiliary electrode, and
the second insulating layer is in contact with the first insulating layer through the at least one opening.

18. An electronic device comprising:
a memory which stores at least one program;
a processor which operates by executing the at least one program;
a display device which provides visual information based on data received by the display device from the processor; and
a power module which supplies power to the display device,
wherein the display device comprises:
a substrate;
a thin-film transistor on the substrate;
a first insulating layer located on the thin-film transistor and comprising a concave portion defined in the first insulating layer;
a light emitting element disposed in the concave portion and electrically connected to the thin-film transistor; and
an auxiliary electrode disposed on a bottom surface and an inner surface of the concave portion and electrically connected to the thin-film transistor and the light emitting element,
wherein the light emitting element comprises:
a pixel electrode in contact with a portion of the auxiliary electrode disposed on the inner surface of the concave portion;
an intermediate layer located on the pixel electrode; and
a common electrode located on the intermediate layer.

19. The electronic device of claim 18, further comprising a connecting electrode extending through the first insulating layer and electrically connecting the auxiliary electrode and the thin-film transistor to each other.

20. The electronic device of claim 18, further comprising a second insulating layer located between the auxiliary electrode and the pixel electrode.
